(19) United States
(12) Patent Application Publication
(10) Pub. No.: US 2015/0137356 A1
(43) Pub. Date: May 21, 2015

(54) NON-CYANIDE ELECTROLYTIC GOLD PLATING SOLUTION

(71) Applicant: ELECTROPLATING ENGINEERS OF JAPAN LIMITED, Tokyo (JP)

(72) Inventors: Junko Tsuyuki, Kanagawa (JP); Masahiro Ito, Kanagawa (JP)

(73) Assignee: ELECTROPLATING ENGINEERS OF JAPAN LIMITED, Tokyo (JP)

(21) Appl. No.: 14/411,904

(22) PCT Filed: Sep. 19, 2013
(86) PCT No.: PCT/JP2013/075305

§ 371 Date: Dec. 29, 2014

(30) Foreign Application Priority Data
Oct. 4, 2012 (JP) 2012-221769

(51) Int. Cl. C25D 3/48; H01L 23/00; C25D 7/12

(52) U.S. Cl. CPC C25D 3/48; C25D 7/12; H01L 24/13; H01L 24/45; H01L 24/11; H01L 24/43; H01L 2924/01079
USPC 257/737; 205/266; 205/123; 257/741

(57) ABSTRACT

The present invention provides a non-cyanogen type electrolytic gold plating solution, which can form a plating film capable of maintaining a high hardness even when the plating film is subjected to a heat treatment. A non-cyanogen type electrolytic gold plating solution of the present invention includes: a gold source including an alkaline salt of gold sulfite or ammonium of gold sulfite; and a conductive salt including sulfite and sulfate. The non-cyanogen type electrolytic gold plating solution includes a salt of at least one of iridium, ruthenium, and rhodium in a metal concentration of 1 to 3000 mg/L. Further, the non-cyanogen type electrolytic gold plating solution preferably includes a crystal adjuster. The crystal adjuster is particularly preferably thallium.

### BACKGROUND OF THE INVENTION

1. Field of the Invention

The present invention relates to a non-cyanogen type electrolytic gold plating solution, and in particular to a non-cyanogen type electrolytic gold plating solution capable of carrying out a gold plating treatment suitable for forming a bump, and a gold plating method using the same.

2. Description of the Related Art

A gold plating treatment is widely utilized in industrial fields such as electronic parts, electric parts, and audio equipment parts from the excellent electrical property of the gold plating treatment. For example, the gold plating treatment is frequently utilized in order to secure electrical joining when a bump is formed in an electronic part such as an electric element of a semiconductor.

Various cyanogen type and non-cyanogen type gold plating solutions are proposed as a gold plating solution used for the gold plating treatment. The cyanogen type gold plating solution includes a gold cyanide salt as a gold supply source. Since the cyanogen type plating solution has high stability and an easily-controlled plating condition, and is inexpensive in itself, the cyanogen type gold plating solution is conventionally widely used. However, in recent years, many non-cyanogen type electrolytic gold plating solutions are proposed from the viewpoint of environmental problems or the like. For example, a non-cyanogen type electrolytic gold plating solution is known, which includes a gold sulfite salt such as sodium gold sulfite as a gold supply source (see Patent Documents 1 and 2).

Recent years, an electric element to be manufactured is made to be surprisingly lighter and more compact, and a bump having a minute shape is formed. Recently, a bump of tens of micrometer square is also formed. When the minute bump is formed, the hardness of the bump after a heat treatment is an important factor. In the case of the minute bump, a gap between the bumps, and a gap between the bump and a wiring circuit or the like are decreased. When the hardness of the bump after the heat treatment is low, the reliability of electrical connection provided by the bump tends to be decreased, and a failure such as a short circuit (short) tends to be caused.

In order to increase the hardness of gold plating after the heat treatment, the addition of an organic compound to a non-cyanogen type electrolytic gold plating solution has been proposed (see Patent Document 2). However, there has been also pointed out a problem that solution stability cannot be secured by the decomposition and consumption of the organic compound.

### PRIOR ART DOCUMENT

### Patent Document

### Patent Document 1

Japanese Patent Application Laid-Open No. 2008-115449

### Patent Document 2

Japanese Patent Application Laid-Open No. 2008-115450

### SUMMARY OF THE INVENTION

### Technical Problem

The present invention has been made against a backdrop of the above circumstances, and it is an object of the present invention to provide a non-cyanogen type electrolytic gold plating solution capable of forming gold plating achieving a high plating hardness even when the gold plating is subjected to a heat treatment.

### Solution to Problem

The present inventors have conducted earnest studies on various additive agents in a conventional non-cyanogen type electrolytic gold plating solution. As a result, a gold plating solution according to the present invention was attained.

A non-cyanogen type electrolytic gold plating solution according to the present invention includes: a gold source including an alkaline salt of gold sulfite or ammonium of gold sulfite; and a conductive salt including sulfite and sulfate. The non-cyanogen type electrolytic gold plating solution includes a salt of at least one of iridium, ruthenium, and rhodium in a metal concentration of 1 to 3000 mg/L. Since the present invention can form a gold plating film having a high hardness after a heat treatment, the deformation of the shape of a bump by a crimping force or the like during joining, for example, deformation such as the crushing of the bump can be effectively prevented even when a minute gold bump is formed, which can achieve an improvement in the reliability of the gold bump.

When the salt of at least one of iridium, ruthenium, and rhodium in the present invention is included in a metal concentration of less than 1 mg/L, a hardness after the heat treatment tends to be decreased. When the salt is included in a metal concentration of more than 3000 mg/L, iridium and ruthenium are less likely to be dissolved, which tends to generate a precipitation. At least one of iridium and ruthenium is included in metal concentration of preferably 1 mg/L to 50 mg/L, and more preferably 3 mg/L to 30 mg/L.

Preferably, the non-cyanogen type electrolytic gold plating solution according to the present invention further includes a crystal adjuster. The non-cyanogen type electrolytic gold plating solution includes the crystal adjuster, which accelerates the deposition of gold plating. The crystal adjuster is preferably thallium, bismuth, lead, and antimony or the like, and particularly preferably thallium.

In the present invention, the non-cyanogen type electrolytic gold plating solution preferably includes the gold source in a gold concentration of 5 to 20 g/L, the crystal adjuster in a concentration of 1 to 50 mg/L, and the conductive salt in a concentration of 50 to 300 g/L. When the gold concentration is less than 5 g/L, crystals of the plating film tend to be coarse. The gold concentration of more than 20 g/L is disadvantageous costwise. When the crystal adjuster is included in a concentration of less than 1 mg/L, the hardness after the heat treatment tends to be too low. When the crystal adjuster is included in a concentration of more than 50 mg/L, the crystals of the plating film tends to be coarse.

The non-cyanogen type electrolytic gold plating solution in the present invention is preferably used to conduct an electrolytic plating under conditions of a current density of 0.2 to 2.0 A/dm² and a solution temperature of 40 to 65° C. When the current density is less than 0.2 A/dm², the crystals tend to be coarse. When the current density is more than 2.0 A/dm², burning plating tends to be applied. When the solution temperature is lower than 40° C., the crystals tend to be too fine. When the solution temperature is more than 65° C., the crystals tend to be coarse. For practical purposes, it is particularly preferable that the current density is 0.2 to 1.2 A/dm², and the solution temperature is 50 to 60° C.

The non-cyanogen type electrolytic gold plating solution according to the present invention is very suitable when a substrate such as a wafer is subjected to an electrolytic gold plating treatment and patterned to form a gold bump and gold wiring. Even when a gold plating film (15 μm) formed by the non-cyanogen type electrolytic gold plating solution according to the present invention is subjected to a heat treatment at 250° C. for 2 hours, the gold plating film having a Vickers hardness of 70 Hv or more can be achieved. Furthermore, even when the gold plating film (15 μm) formed by the non-cyanogen type electrolytic gold plating solution according to the present invention is subjected to a high temperature heat treatment at 300° C. for 2 hours, the gold plating film having a high Vickers hardness of 70 Hv or more can be possibly achieved.

To the non-cyanogen type electrolytic gold plating solution according to the present invention, an antioxidant for improving the stability of the solution, a smoothing agent for improving the smoothness of a deposit, or a surface-active agent for lowering the surface tension of the plating solution can also be suitably added.

When the gold plating film is formed by the gold plating solution according to the present invention, the gold plating film includes iridium, ruthenium, and rhodium of 0.05 wt % or less. Iridium, ruthenium, and rhodium included in the film are presumed to have a function of maintaining the gold plating hard even when the heat treatment is performed.

### Advantageous Effects of Invention

A non-cyanogen type electrolytic gold plating solution of the present invention can achieve a gold plating film having a high hardness even when the gold plating film is subjected to a heat treatment at 250° C.

### DETAILED DESCRIPTION OF THE PREFERRED EMBODIMENTS

Hereinafter, embodiments of the present invention will be described with reference to Examples.

First Embodiment: the results of consideration on a non-cyanogen type electrolytic gold plating solution including iridium (Ir) will be described in First Embodiment. First, Table 1 shows compositions of electrolytic gold plating solutions in which iridium concentrations have been considered.

TABLE 1

| | | | Surface | Hardness (Hv) |
|---|---|---|---|---|
| | | | roughness | upper: As-depo |
| | Iridium | Thallium | Ra | lower: after |
| | mg/L | mg/L | Å | treatment at 250° C. |
| Example 1-1 | 1 | | 800.5 | 120.0 |
| | | | | 70.2 |
| Example 1-2 | 10 | | 840.1 | 116.5 |
| | | | | 77.3 |
| Example 1-3 | 100 | | 1700.7 | 103.6 |
| | | | | 80.6 |
| Example 1-4 | 1000 | | 1805.7 | 91.1 |
| | | | | 73.0 |
| Example 1-5 | 3000 | | 1900.6 | 89.3 |
| | | | | 71.1 |
| Comparative | 0 | | 3000.5 | 80.1 |
| Example 1-1 | | | | 60.5 |
| Comparative | 0.5 | | 2960.5 | 85.5 |
| Example 1-2 | | | | 65.1 |
| Comparative | 5000 | | — | — |
| Example 1-3 | | | | — |

Gold source: sodium gold sulfite (concentration in terms of gold: 15 g/L)
Ir: iridium compound, sodium hexabromoiridate
Conductive salt: sodium sulfite 50 g/L
Solution temperature: 60° C.
Current density: 0.8 A/dm²

For comparison, a gold plating solution free of Ir and gold plating solutions having an Ir content range departing from that in the present invention were evaluated (Comparative Examples 1-1 to 1-3). In order to evaluate each gold plating solution, the hardness of a gold plating film was measured, and a surface roughness and appearance after a bump was formed were observed.

Each gold plating solution shown in Table 1 was produced. An Au thin film was formed on the surface of an Au sputtering wafer substrate by sputtering. On the surface of the Au sputtering wafer substrate, a test sample substrate was prepared, to which a resist patterned so that a square bump (height: 15 μm) having a size of 40 μm×60 μm could be formed was applied. Each gold plating solution was used to conduct a gold plating treatment at a current density of 0.8 A/dm² and a solution temperature of 60° C.

The resist was removed, and the hardness and roughness of the surface of the square-columnar bump were then measured. The results are shown in Table 1.

Each heat treatment was performed in a nitrogen atmosphere at a heat treatment temperature of 250° C. for 2 hours to measure the Vickers hardness of gold plating before and after the heat treatment. The Vickers hardness was measured at five places with a microhardness tester <manufactured by Future-Tech Corp.>with a load set to 15 g and a load time set to 15 seconds. The average value of the five places was used as a hardness value. A surface roughness Ra was measured with a surface roughness tester (Tencor: manufactured by KLA-Tencor).

From the results shown in Table 1, it was found that the gold plating solutions of Examples 1-1 to 5 provide the hardness of 70 Hv or more after the heat treatment, and can maintain the high hardness. The surface roughness Ra was a practical surface roughness of 400 Angstrom to 2000 Angstrom required from the adhesion characteristics of the bump. On the other hand, when the plating solution was produced in Comparative Example 1-3, a precipitation was generated, and which prevented a gold plating treatment from being performed. In Comparative Example 1-1 having a solution composition free of iridium, the hardness after the heat treatment was as low as 60.5. Also in Comparative Example 1-2 having a solution composition including 0.5 mg/L of iridium, the hardness after the heat treatment was as low as 65.1.

Next, the results of consideration on the relationship between iridium and a crystal adjuster (thallium) will be described. Table 2 shows the compositions of the evaluated plating solutions. The hardness and roughness of the gold plating film formed with each gold plating solution were measured. A test sample substrate, plating, and a measurement condition were set to be the same as those described in Table 1. The results of the hardness and roughness are also shown in Table 2.

TABLE 2

| | | | Surface | Hardness (Hv) |
|---|---|---|---|---|
| | | | roughness | upper: As-depo |
| | Iridium | Thallium | Ra | lower: after |
| | mg/L | mg/L | Å | treatment at 250° C. |
| Example 1-6 | 1 | 30 | 920.5 | 100.8 |
| | | | | 92.2 |
| Example 1-7 | 10 | | 755.5 | 115.6 |
| | | | | 102.0 |
| Example 1-8 | 50 | | 764.5 | 105.4 |
| | | | | 108.9 |
| Example 1-9 | 100 | | 687.7 | 134.9 |
| | | | | 94.4 |
| Example 1-10 | 1 | 50 | 1106.8 | 92.0 |
| | | | | 91.5 |
| Example 1-11 | 100 | | 428.9 | 133.7 |
| | | | | 127.4 |
| Example 1-12 | 1000 | | 1796.7 | 114.6 |
| | | | | 87.5 |
| Example 1-13 | 3000 | | 2103.1 | 117.1 |
| | | | | 84.3 |
| Comparative | — | 50 | 1298.6 | 94.5 |
| Example 1-4 | | | | 63.2 |
| Comparative | 0.5 | 10 | 736.7 | 107.1 |
| Example 1-5 | | | | 55.9 |
| Comparative | 5000 | 50 | — | — |
| Example 1-6 | | | | — |

Gold source: sodium gold sulfite (concentration in terms of gold: 15 g/L)
Ir: iridium compound, sodium hexabromoiridate
Crystal adjuster: thallium formate
Conductive salt: sodium sulfite 50 g/L
Solution temperature: 60° C.
Current density: 0.8 A/dm²

From the results of Table 2, it was found that thallium is added as the crystal adjuster, and thereby the characteristics for the surface roughness and the hardness are equivalent to, or slightly better than those of the gold plating solution shown in Table 1 and free of thallium. Furthermore, in the case of Table 1 in which no thallium was added, the plating appearance had a coarse plating surface, and was uneven. By contrast, in the case of Table 2 in which thallium was added, the plating appearance had a smooth surface.

Second Embodiment the results of consideration on a non-cyanogen type electrolytic gold plating solution including ruthenium (Ru) will be described in Second Embodiment. First, Table 3 shows compositions of electrolytic gold plating solutions in which ruthenium concentrations were considered.

TABLE 3

| | | | Surface | Hardness (Hv) |
|---|---|---|---|---|
| | | | roughness | upper: As-depo |
| | Ruthenium | Thallium | Ra | lower: after |
| | mg/L | mg/L | Å | treatment at 250° C. |
| Example 2-1 | 10 | | 1200.3 | 100.5 |
| | | | | 70.6 |
| Example 2-2 | 30 | | 1105.8 | 103.8 |
| | | | | 72.5 |
| Example 2-3 | 50 | | 1800.5 | 109.7 |
| | | | | 80.5 |
| Comparative | 0 | | 1600.5 | 105.3 |
| Example 2-1 | | | | 59.1 |
| Comparative | 4000 | | — | — |
| Example 2-2 | | | | — |

Gold source: sodium gold sulfite (concentration in terms of gold: 15 g/L)
Ru: ruthenium chloride
Conductive salt: sodium sulfite 50 g/L
Solution temperature: 55° C.
Current density: 0.8 A/dm²

For comparison, a gold plating solution free of Ru and a gold plating solution having a Ru content range beyond that in the present invention were evaluated. In order to evaluate each gold plating solution, the hardness of a gold plating film was measured, and a surface roughness after a bump had been formed was measured. Each valuation method is the same as that of First Embodiment. The results are shown in Table 3.

From the results shown in Table 3, it was found that the gold plating solutions of Examples 2-1 to 3 provide the hardness of 70 Hv or more after the heat treatment at 250° C., and can maintain the high hardness. The surface roughness Ra was a practical surface roughness of 400 Angstrom to 2000 Angstrom required from the adhesion characteristics of the bump. On the other hand, in the case of Comparative Example 2-1 free of ruthenium, the hardness after the heat treatment was as low as 60 Hv. When ruthenium was included in a concentration of 4000 mg/L, a precipitation was generated in the plating solution, which prevented the plating treatment from being performed.

Next, the results of consideration on the relationship between ruthenium and a crystal adjuster (thallium) will be described. Table 4 shows the compositions of the evaluated plating solutions. The hardness and roughness of the gold plating film formed with each gold plating solution were measured. A test sample substrate, plating, and a measurement condition were set to be the same as those described in First Embodiment. The results of the hardness and roughness are also shown in Table 4.

TABLE 4

| | | | Surface | Hardness (Hv) |
|---|---|---|---|---|
| | | | roughness | upper: As-depo |
| | Ruthenium | Thallium | Ra | lower: after |
| | mg/L | mg/L | Å | treatment at 250° C. |
| Example 2-4 | 10 | 14 | 1469.9 | 108.2 |
| | | | | 84.1 |
| Example 2-5 | 30 | | 786.9 | 112.4 |
| | | | | 107.7 |
| Example 2-6 | 50 | | 1509.1 | 125.1 |
| | | | | 115.6 |
| Comparative | 0 | 14 | 2070.8 | 91.5 |
| Example 2-3 | | | | 60.7 |
| Comparative | 4000 | | — | — |
| Example 2-4 | | | | — |

Gold source: sodium gold sulfite (concentration in terms of gold: 15 g/L)

Ru: ruthenium chloride

Crystal adjuster: thallium formate

Conductive salt: sodium sulfite 50 g/L
Solution temperature: 55° C.
Current density: 0.8 A/dm²

From the results of Table 4, it was found that thallium is added as the crystal adjuster, and thereby the characteristics for the surface roughness and the hardness are equivalent to, or slightly better than those of the gold plating solution shown in Table 3 and free of thallium. Furthermore, in the case of Table 3 in which no thallium was added, the plating appearance had a coarse plating surface, and was uneven. By contrast, in the case of Table 4 in which thallium was added, the plating appearance had a smooth surface.

Third Embodiment: the results of consideration on a non-cyanogen type electrolytic gold plating solution including rhodium (Rh) will be described in Third Embodiment. In the case of rhodium, the presence or absence of a crystal adjuster (thallium) was also evaluated together. Table 5 shows compositions of considered electrolytic gold plating solutions.

TABLE 5

| | | | Surface | Hardness (Hv) |
|---|---|---|---|---|
| | | | roughness | upper: As-depo |
| | Rhodium | Thallium | Ra | lower: after |
| | mg/L | mg/L | Å | treatment at 250° C. |
| Example 3-1 | 10 | | 2001.3 | 90.3 |
| | | | | 70.1 |
| Comparative | 0 | | 3000.5 | 80.1 |
| Example 3-1 | | | | 60.5 |
| Example 3-2 | 10 | 30 | 1900.1 | 97.9 |
| | | | | 80.3 |
| Comparative | 0 | 30 | 1117.3 | 90.8 |
| Example 3-2 | | | | 68.7 |

Gold source: sodium gold sulfite (concentration in terms of gold: 15 g/L)
Rh: rhodium sulfate
Crystal adjuster: thallium formate
Conductive salt: sodium sulfite 50 g/L
Solution temperature: 60° C.
Current density: 0.8 A/dm²

In order to evaluate each gold plating solution, the hardness of a gold plating film was measured, and a surface roughness after a bump had been formed was measured. Each valuation method is the same as that of First Embodiment. The results are shown in Table 4.

From the results shown in Table 5, it was found that the gold plating solution including rhodium only, or rhodium and thallium provides the hardness of 70 Hv or more after the heat treatment, and can maintain the high hardness. The surface roughness Ra was a practical surface roughness of 400 Angstrom to 2000 Angstrom required from the adhesion characteristics of the bump. On the other hand, when no ruthenium was included, the hardness after the heat treatment was lower than 70 Hv. Furthermore, in the case of Example 3-1 in which no thallium was added, the plating appearance had a coarse plating surface, and was uneven. By contrast, the plating appearance in the case of Example 3-2 in which thallium was added had a smoother surface than that of Example 3-1.

Fourth Embodiment: a case where a gold bump formed by a non-cyanogen type electrolytic gold plating solution including iridium (Ir) is subjected to a high temperature heat treatment at 300° C. will be described in Fourth Embodiment. The gold plating electrolytic solution forming the gold bump is as follows. The formation of the gold bump, and the measurement of a hardness and surface roughness are the same as those of First Embodiment.

Gold source: sodium gold sulfite (concentration in terms of gold: 15 g/L)
Ir: iridium compound, sodium hexabromoiridate (iridium concentration: 10 mg/L)
Crystal adjuster: thallium formate (thallium concentration: 15 mg/L)
Conductive salt: sodium sulfite 50 g/L
Solution temperature: 55° C.
Current density: 0.8 A/dm²

The hardness of the formed gold bump before the heat treatment and the hardness of the gold bump after the high temperature heat treatment at 300° C. for 2 hours were measured. The hardness before the heat treatment was 117.3 Hv, and the hardness after the heat treatment was 97.5 Hv.

### INDUSTRIAL APPLICABILITY

Since a gold plating film capable of maintaining a high hardness even when the gold plating film is subjected to a heat treatment can be formed by a non-cyanogen type electrolytic gold plating solution according to the present invention, a bump suitable for an electric element or the like can be formed.

1. A non-cyanogen type electrolytic gold plating solution comprising:
a gold source comprising an alkaline salt of gold sulfite or ammonium of gold sulfite; and
a conductive salt comprising sulfite and sulfate,
wherein the non-cyanogen type electrolytic gold plating solution comprises a conductive salt of at least one of iridium, ruthenium, and rhodium in a metal concentration of 1 to 3000 mg/L.

2. The non-cyanogen type electrolytic gold plating solution according to claim 1, further comprising a crystal adjuster.

3. The non-cyanogen type electrolytic gold plating solution according to claim 2, wherein the crystal adjuster is thallium.

4. The non-cyanogen type electrolytic gold plating solution according to claim 2, wherein the non-cyanogen type electrolytic gold plating solution comprises the gold source in a gold concentration of 5 to 20 g/L, the crystal adjuster in a concentration of 1 to 50 mg/L, and the conductive salt in a concentration of 50 to 300 g/L.

5. A method for forming a gold bump or gold wiring, comprising the step of subjecting a patterned wafer to electrolytic gold plating with the non-cyanogen type electrolytic gold plating solution defined in claim 1.

6. An electronic part manufactured by the method for forming a gold bump or gold wiring defined in claim 5.

7. The non-cyanogen type electrolytic gold plating solution according to claim 3, wherein the non-cyanogen type electrolytic gold plating solution comprises the gold source in a gold concentration of 5 to 20 g/L, the crystal adjuster in a concentration of 1 to 50 mg/L, and the conductive salt in a concentration of 50 to 300 g/L.

8. A method for forming a gold bump or gold wiring, comprising the step of subjecting a patterned wafer to electrolytic gold plating with the non-cyanogen type electrolytic gold plating solution defined in claim 2.

9. A method for forming a gold bump or gold wiring, comprising the step of subjecting a patterned wafer to electrolytic gold plating with the non-cyanogen type electrolytic gold plating solution defined in claim 3.

10. A method for forming a gold bump or gold wiring, comprising the step of subjecting a patterned wafer to electrolytic gold plating with the non-cyanogen type electrolytic gold plating solution defined in claim 4.

11. A method for forming a gold bump or gold wiring, comprising the step of subjecting a patterned wafer to electrolytic gold plating with the non-cyanogen type electrolytic gold plating solution defined in claim 7.

12. An electronic part manufactured by the method for forming a gold bump or gold wiring defined in claim 8.

13. An electronic part manufactured by the method for forming a gold bump or gold wiring defined in claim 9.

14. An electronic part manufactured by the method for forming a gold bump or gold wiring defined in claim 10.

15. An electronic part manufactured by the method for forming a gold bump or gold wiring defined in claim 11.
